(19) United States
(12) Patent Application Publication
(10) Pub. No.: US 2024/0357731 A1
(43) Pub. Date: Oct. 24, 2024

(54) INTERFERENCE SHIELDING IN COMPACT ELECTRONIC DEVICES

(71) Applicant: PLUME DESIGN, INC., Palo Alto, CA (US)

(72) Inventors: Miroslav SAMARDZIJA, Mountain View, CA (US); Ming-Tsung SU, Taipei (TW); Yun-Ping HUANG, Santa Clara, CA (US); Chun-Hung LIU, Taipei (TW); Yu-Han LIU, Taipei (TW); Liem Hieu Dinh VO, San Jose, CA (US)

(21) Appl. No.: 18/302,152

(22) Filed: Apr. 18, 2023

(51) Int. Cl. H05K 1/02; H05K 7/20; H05K 9/00

(52) U.S. Cl. CPC H05K 1/0216; H05K 7/2039; H05K 9/0024

(57) ABSTRACT

Disclosed is a system and/or apparatus for a specifically configured and/or adapted electronic device that can provide interference shielding. The disclosed system and apparatus can be embodied with various combinations of components to effectuate improved thermal resistance while reducing noise within the device and/or among components of the device. The specifically configured components of the device can have specifically configured constitutions which can effectuate the thermal and noise limiters enabled by the disclosed system/apparatus.

### FIELD OF THE DISCLOSURE

The present disclosure is generally related to compact electronic devices, and more particularly, to a compact electronic device with interference shielding configurations and/or components.

### BACKGROUND

Conventional electronic devices, such as consumer devices, for example, may be fit and/or include components including built-in radios, power amplifiers, low noise amplifiers, front end modules, electronic switches, programmable and storage memories, and the like. However, most, if not all of such components, particularly the active ones, are not adequately shielded, and may exhibit undesired radiation and/or noise impacting other components, thereby degrading the performance of the device. For example, radio sensitivity may be impacted thereby resulting in a loss of data signals and/or poor device functionality given the unchecked interference signals within the device.

### SUMMARY OF THE DISCLOSURE

Accordingly, disclosed is a novel system, device and apparatus that involves a specifically configured and/or adapted electronic device that can provide interference shielding. According to some embodiments, the disclosed system, device and apparatus can be embodied with various combinations of components to effectuate improved thermal resistance while reducing noise within the device and/or among components of the device. In some embodiments, the specifically configured components of the device can have specifically configured constitutions which can effectuate the thermal and noise limiters enabled by the disclosed system/apparatus, as discussed in more detail below.

According to some embodiments, the disclosed system and incorporated configurations discussed herein, can protect electronic devices or systems from electromagnetic interference (EMI) or radio frequency interference (RFI). In some embodiments, the disclosed systems can provide improved device performance, enhanced signal integrity, improved electromagnetic compatibility (EMC), improved safety, and the like. That is, for example, the disclosed interference shielding can help to reduce EMI/RFI noise and other types of interference that can disrupt the operation of electronic devices. This can lead to improved performance, reliability, and stability.

In another non-limiting example, by reducing EMI/RFI noise, the disclosed interference shielding can help to improve the quality and integrity of electronic signals. For example, this can be particularly important for high-speed data transmission or sensitive electronic devices. Moreover, the disclosed interference shielding can help to ensure that electronic devices are compatible with each other and with other equipment in the same environment. For example, this can help to prevent interference and other problems that can occur when multiple electronic devices are operating in close proximity.

In yet another non-limiting example, the disclosed interference shielding can help to protect electronic devices from potentially harmful EMI/RFI radiation. For example, this can be particularly important for home devices (e.g., charging stations, access points, and the like), medical devices, aerospace equipment, and other safety-critical applications.

Accordingly, as discussed herein, the disclosed interference shielding can provide a range of benefits, from improved device performance and signal integrity to enhanced safety and regulatory compliance.

### DESCRIPTIONS OF THE DRAWINGS

The features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure:

FIGS. 1-3 provide illustrative environments for which the disclosed systems and configurations can be implemented according to some embodiments of the present disclosure;

FIGS. 4A-4B depict non-limiting example embodiments according to some embodiments of the present disclosure;

FIGS. 5A-5B depict non-limiting example embodiments according to some embodiments of the present disclosure;

FIGS. 6A-6B depict non-limiting example embodiments according to some embodiments of the present disclosure;

FIG. 7 depicts a non-limiting example embodiment according to some embodiments of the present disclosure;

FIG. 8 depicts a non-limiting example embodiment according to some embodiments of the present disclosure;

FIGS. 9A-9B depict non-limiting example embodiments according to some embodiments of the present disclosure;

FIGS. 10A-10B depict non-limiting example embodiments according to some embodiments of the present disclosure;

FIG. 11 depicts a non-limiting example embodiment according to some embodiments of the present disclosure;

FIGS. 12A-12B depict non-limiting example embodiments according to some embodiments of the present disclosure;

FIG. 13A-13B depict non-limiting example embodiments according to some embodiments of the present disclosure;

FIG. 14 depicts a non-limiting example embodiment according to some embodiments of the present disclosure;

FIG. 15 depicts a non-limiting example embodiment according to some embodiments of the present disclosure;

FIG. 16 depicts a non-limiting example embodiment according to some embodiments of the present disclosure; and

FIG. 17 depicts a non-limiting example embodiment according to some embodiments of the present disclosure.

### DETAILED DESCRIPTION

The present disclosure will now be described more fully hereinafter with reference to the accompanying drawings, which form a part hereof, and which show, by way of non-limiting illustration, certain example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware or any combination thereof (other than software per se). The following detailed description is, therefore, not intended to be taken in a limiting sense.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of example embodiments in whole or in part.

In general, terminology may be understood at least in part from usage in context. For example, terms, such as “and”, “or”, or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

The present disclosure is described below with reference to block diagrams and operational illustrations of methods and devices. It is understood that each block of the block diagrams or operational illustrations, and combinations of blocks in the block diagrams or operational illustrations, can be implemented by means of analog or digital hardware and computer program instructions. These computer program instructions can be provided to a processor of a general purpose computer to alter its function as detailed herein, a special purpose computer, ASIC, or other programmable data processing apparatus, such that the instructions, which execute via the processor of the computer or other programmable data processing apparatus, implement the functions/acts specified in the block diagrams or operational block or blocks. In some alternate implementations, the functions/acts noted in the blocks can occur out of the order noted in the operational illustrations. For example, two blocks shown in succession can in fact be executed substantially concurrently or the blocks can sometimes be executed in the reverse order, depending upon the functionality/acts involved.

Certain embodiments and principles will be discussed in more detail with reference to the figures.

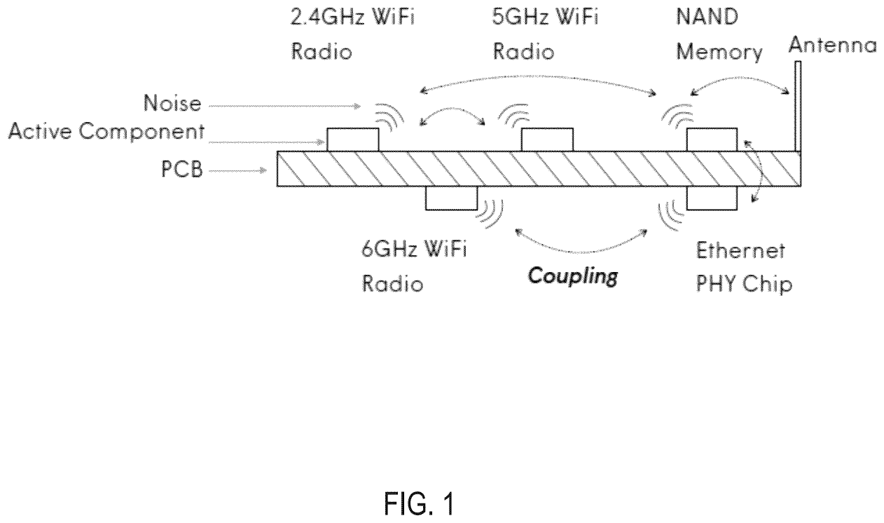

With reference to FIG. 1, conventional high-performance electronic devices can have multiple components built-in and/or connected to their circuit boards (e.g., radio frequency (RF) boards, printed circuit boards (PCB), for example). For example, such components can include, but are not limited to, radios (e.g., Wi-Fi radios, Bluetooth® radios, cellular radios, for example), amplifiers, switches, memories, antennas, chips (e.g., Ethernet chip, for example), and the like. Accordingly, if/when such components are not shielded, they may exhibit undesired radiation and/or noise that may couple to other components, which may lead to a degradation of the device's and/or included components' performance. For example, a Wi-Fi radio on the device may experience reduced sensitivity to signals it was specifically configured to detect.

In some embodiments, a non-limiting example of how noise, and/or other types of interference, can impact device components is illustrated in FIG. 1. For example, the 2.4 GHz Wi-Fi radio may experience a shortened range due to the noise occurring within device components.

Conventional mechanisms to address such shortcomings involve the usage of a shield can(s). A shield can be made from metallic parts, or from plastic parts with metallic paint, splatter, and the like, or some combination thereof.

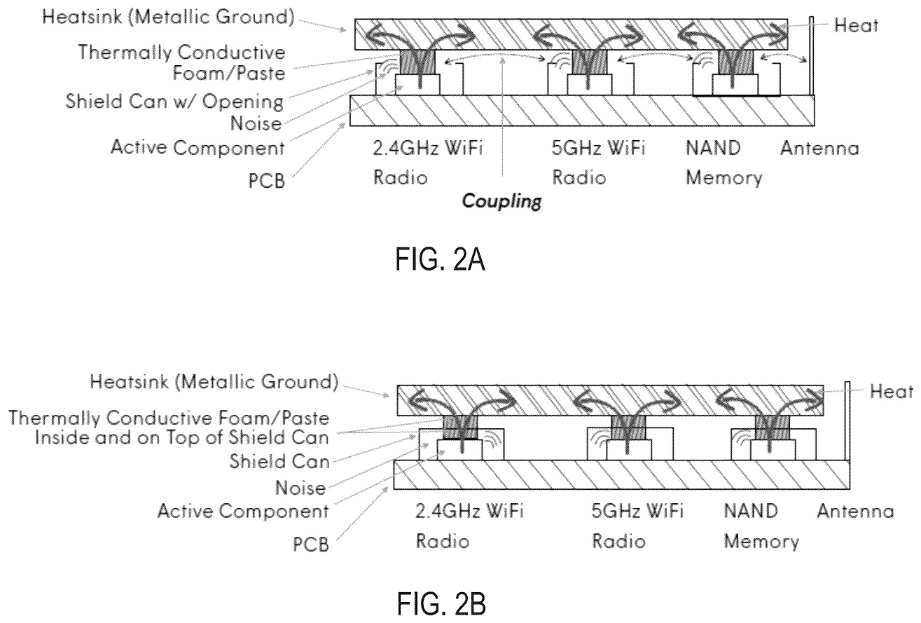

For example, as depicted in FIGS. 2A-2B, a shield can be used to encapsulate a component in order to prevent its undesired radiation from coupling to other components on a circuit board (for example, a PCB such as, but not limited to, a main logic board, motherboard, power board, and the like). FIG. 2A depicts the usage of a shield can with an opening, and FIG. 2B depicts a “closed” shield can (e.g., without an opening). However, the shield can in FIG. 2A suffers from interference effects since the opening in the shield can enables such unwanted signals to escape from the shield can. For example, at most, some noise escapes, and at worst, all the noise escapes. Furthermore, a typical amount of heat can range from a few watts to 30-40 watts, or more.

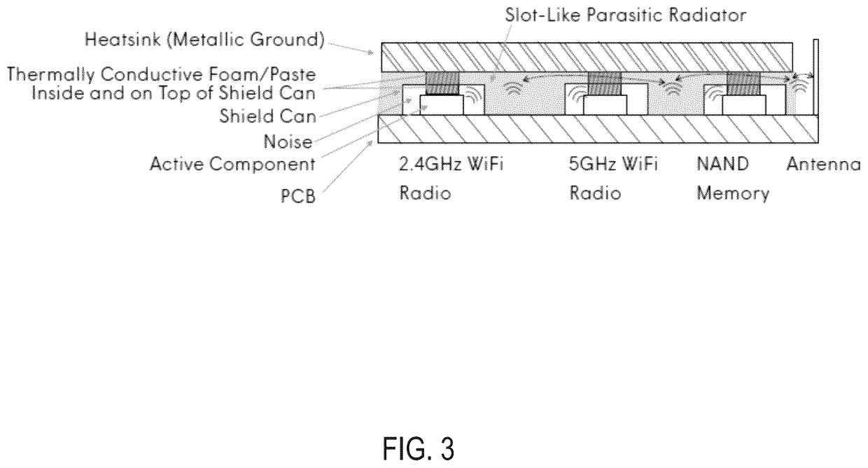

If this heat is not managed, it may damage and/or shorten the life of the active components. Thus, as in FIG. 2B, when shield cans do not have holes (e.g., are closed), multiple thermal conductive materials are needed (e.g., one inside the shield can and one outside/on top of the shield can to conduct heat out from active components to the heatsink. This increases the material cost and assembly cost. Another shortcoming is that the narrow slot(s) can form, which can act as radiating parasitics coupling to signals from the PCB and to the antenna, as depicted in FIG. 3.

Moreover, the shield cans in FIGS. 2B and 3 can reduce a component's coupling capability. For example, the 2.4 GHz radio and the 5 GHZ radio in FIG. 2B may be prevented from coupling given their respective “closed” shield cans.

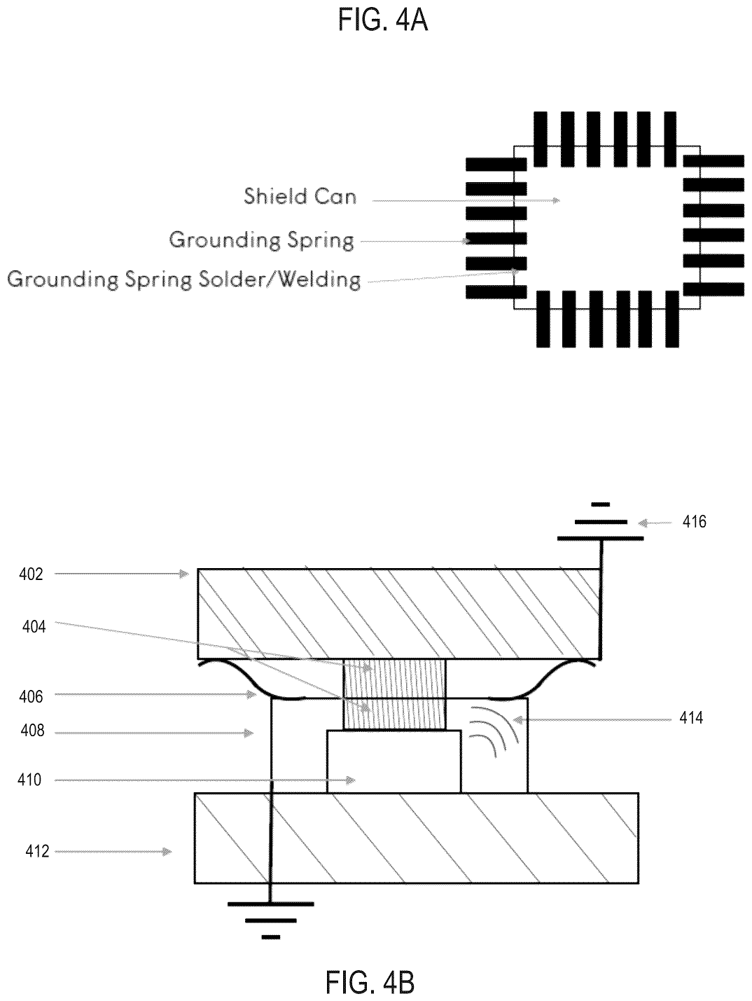

Thus, conventional solutions fall short of addressing the interference shielding (e.g., noise and thermal) needs of modern compact electronic devices. Minimizing, suppressing and/or eliminating undesired radiation from active components is necessary to enable a noise-free environment and to maximize receiver sensitivity. For example, the greater sensitivity of a receiver of a component, the weaker the signals can be detected, which translates to longer ranges of communications and/or higher data throughputs in a communications link(s). The existing implementations in FIGS. 2A-2B and 3 fall short of efficient, accurate and proper operational configurations and/or environments, which are provided via the disclosed implementations, as discussed herein at least in relation to FIGS. 4A-17, infra.

According to some embodiments, with specific deference to the specific configurations of the shield cans discussed below with reference to FIGS. 4A-17, a shield can positioned on a circuit board at least partially around an active component(s), whereby, in some embodiments, a top portion of the shield can may be positioned between the active component and the heatsink. As discussed below, the shield can may include a hole or holes to effectuate thermal conductivity.

Turning to FIGS. 4A-4B, depicted are views of a soldered shield can with “wing springs”. In FIG. 4A, depicted is a top view that depicts a shield can, grounding spring (or “grounding spring finger”, used interchangeably) and grounding spring solder/welding (e.g., how the grounding spring is connected to the shield can, as discussed below). In FIG. 4B, depicted are the heatsink (metallic ground) 402, thermally conductive material (e.g., foam/paste) 404, grounding springs 406 (e.g., “wing spring”), shield can 408, chip (e.g., active component) 410, PCB 412, noise 414 and ground 416.

According to some embodiments, with reference to FIG. 4B (and in a similar manner as discussed in relation to FIGS. 4B, 5B, 6B, 7, 8, 9B, 10B, 12B, 13B, 15 and 17, inter alia), the heatsink 402 can be positioned atop/above the (computer) chip 410, where the conductive material is posited between the heatsink 402 and chip 410.

According to some embodiments, grounding springs 406 can enable grounding of the shield can 408 to the heatsink 402. As depicted in FIG. 4B, two grounding springs 406 are depicted; however, one of skill in the art would understand that any number of grounding springs can be used (e.g., two or more, for example) without departing from the scope of the instant application. Thus, reference to grounding springs throughout the application (e.g., with reference to grounding springs in FIGS. 4A-17) embody such implementations.

In some embodiments, the grounding springs 406 can be flexible (e.g., according to a predetermined range of bend, angular displacement and the like) and allow for gap tolerances (e.g., to a predetermined value) between the shield can 408 and the heatsink 402. In some embodiments, the grounding springs 406 can be made out of one or multiple pieces of material (e.g., metallic and/or plastic, in a similar manner as the shield can discussed supra) that can be soldered (or welded) to the top of the shield can 408. Thus, in some embodiments, the shield can 408 can trap noise 414 and the shield can 408 can be fully sealed with a hole(s) on top. In some embodiments, the grounding springs 406 can enable the reduction in parasitic radiation slotting (as in FIG. 3, supra) into many smaller pieces, such that even if radiation occurs, it will couple less within the frequency of interest for various types of networks (e.g., Wi-Fi, Bluetooth, cellular, ultra-wideband (UWB), and the like.

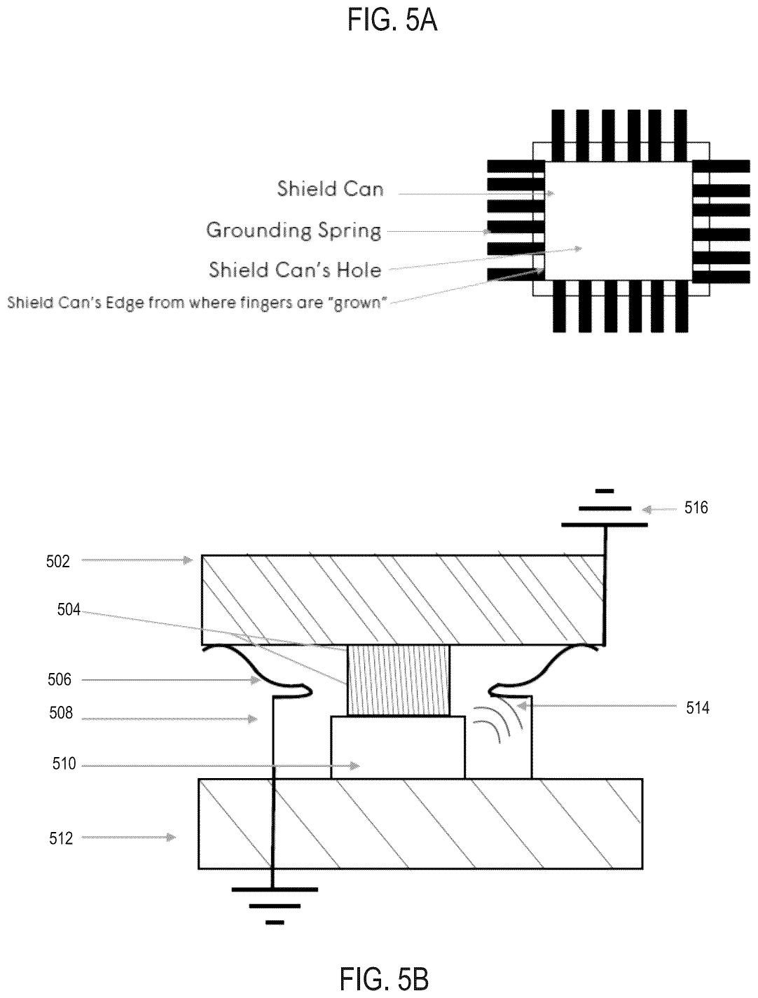

Turning to FIGS. 5A-5B, depicted are views from non-limiting example embodiments for an “M-Spring” grown out of a shield can with a hole(s). FIG. 5A depicts a top view, depicting the shield can, grounding spring and the a shield can's hole(s). FIG. 5B depicts the heatsink (metallic ground) 502, thermally conductive material (e.g., foam/paste) 504, grounding springs 506 (e.g., M-Spring), shield can 508, chip (e.g., active component) 510, PCB 512, noise 514 and ground 516.

According to some embodiments, the grounding springs 506 can operate and/or involve a similar constitution of the grounding springs 406, discussed supra. In some embodiments, the grounding springs 506 can be made out of one or multiple pieces of material (e.g., metallic and/or plastic, in a similar manner as the shield can discussed supra) that can be soldered (or welded) to the top of the shield can 508. In some embodiments, the grounding springs 506 and shield can 508 can be made out of one piece of material (e.g., cut or shaved, for example). Accordingly, the M-Spring grounding springs 506 can minimize noise 514 while increasing thermal efficiency.

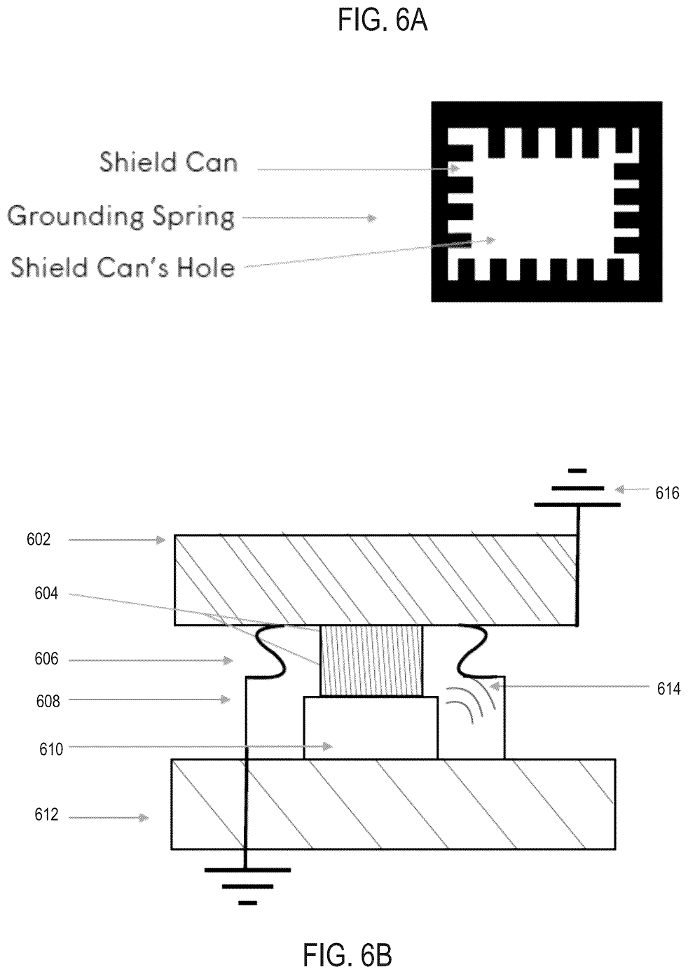

Turning to FIGS. 6A-6B, depicted are views from non-limiting example embodiments for a “S-Spring” grown out of a shield can with a hole(s). FIG. 6A depicts a top view, depicting the shield can, grounding spring and the a shield can's hole(s). FIG. 6B depicts the heatsink (metallic ground) 602, thermally conductive material (e.g., foam/paste) 604, grounding springs 606 (e.g., S-Spring), shield can 608, chip (e.g., active component) 610, PCB 612, noise 614 and ground 616.

According to some embodiments, the grounding springs 606 can operate and/or involve a similar constitution of the grounding springs, discussed supra. In some embodiments, the grounding springs 606 can be made out of one or multiple pieces of material (e.g., metallic and/or plastic, in a similar manner as the shield can discussed supra) that can be soldered (or welded) to the top of the shield can 608. In some embodiments, the grounding springs 606 and shield can 608 can be made out of one piece of material (e.g., cut or shaved, for example). Accordingly, the S-Spring grounding springs 606 can provide less volume around the chip 610, thereby reducing the noise 614.

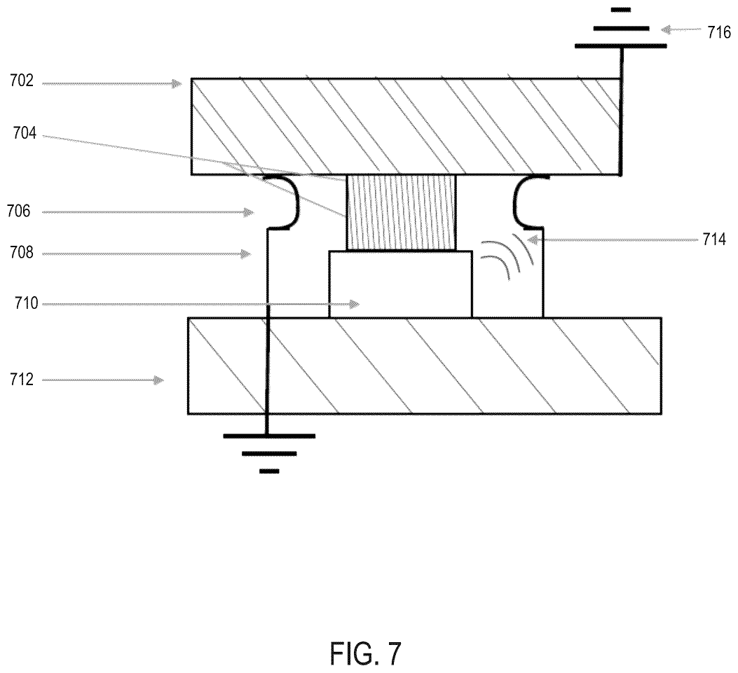

Turning to FIG. 7, depicted is another non-limiting example embodiments for a “C-Spring” grown out of a shield can with a hole(s). In some embodiments, a top view of the C-Spring embodiment is similar to the top view provided in FIG. 6A.

FIG. 7 depicts the heatsink (metallic ground) 702, thermally conductive material (e.g., foam/paste) 704, grounding springs 706 (e.g., C-Spring), shield can 708, chip (e.g., active component) 710, PCB 712, noise 714 and ground 716.

According to some embodiments, the grounding springs 706 can operate and/or involve a similar constitution of the grounding springs, discussed supra. In some embodiments, the grounding springs 706 can be made out of one or multiple pieces of material (e.g., metallic and/or plastic, in a similar manner as the shield can discussed supra) that can be soldered (or welded) to the top of the shield can 708. In some embodiments, the grounding springs 706 and shield can 708 can be made out of one piece of material (e.g., cut or shaved, for example). Accordingly, the C-Spring grounding springs 706 can provide less volume around the chip 710, thereby reducing the noise 714.

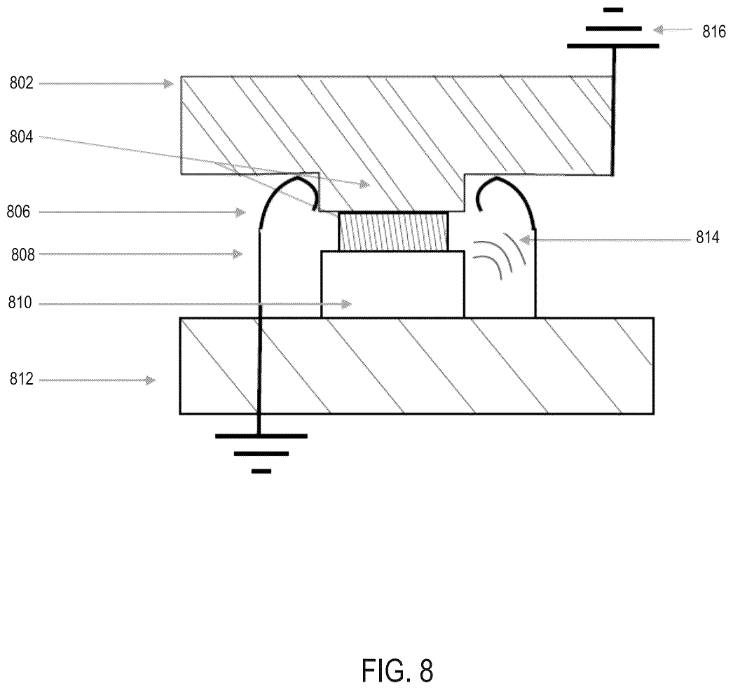

Turning to FIG. 8, depicted is another non-limiting example embodiments for a “Tilt-Spring” grown out of a shield can with a hole(s). In some embodiments, a top view of the Tilt-Spring embodiment is similar to the top view provided in FIG. 6A.

FIG. 8 depicts the heatsink (metallic ground) 802, thermally conductive material (e.g., foam/paste) 804, grounding springs 806 (e.g., Tilt-Spring), shield can 808, chip (e.g., active component) 810, PCB 812, noise 814 and ground 816.

In some embodiments, the heatsink 802 may not need to be rectangular, as depicted in FIG. 8—thus, any other type of shape of a heatsink 802 can be utilized in FIG. 8, and other embodiments discussed herein, as understood by those of skill in the art. For example, the shape of heatsink 802 may enable the usage of less thermal conductive material 804, as depicted in FIG. 8.

According to some embodiments, the grounding springs 806 may not be connected to heatsink 802; however, a portion of the curvature of the grounding springs 806 can be touching the bottom portion of the heatsink 802, as depicted in FIG. 8.

In some embodiments, grounding springs 806 can operate and/or involve a similar constitution of the grounding springs, discussed supra. In some embodiments, the grounding springs 806 can be made out of one or multiple pieces of material (e.g., metallic and/or plastic, in a similar manner as the shield can discussed supra) that can be soldered (or welded) to the top of the shield can 808. In some embodiments, the grounding springs 806 and shield can 808 can be made out of one piece of material (e.g., cut or shaved, for example). Accordingly, the Tilt-Spring grounding springs 806 can minimize noise 714 while maximizing thermal efficiency.

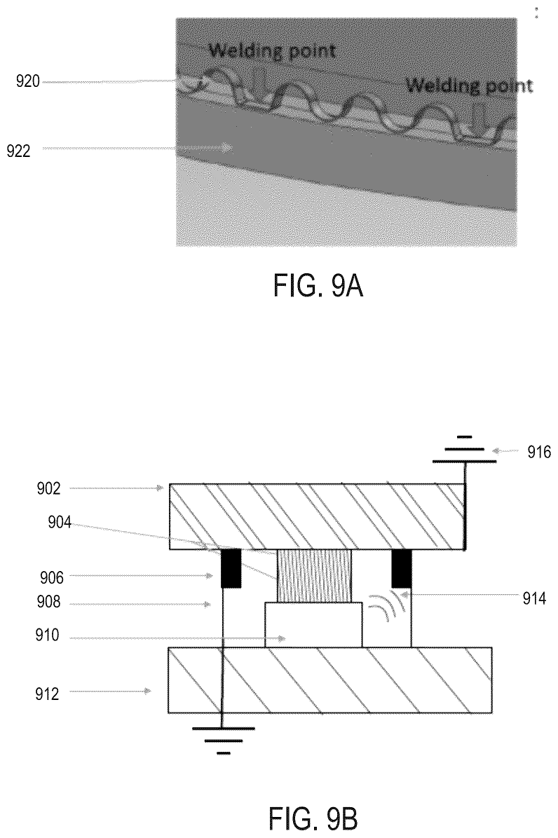

Turning to FIGS. 9A-9B, depicted are views from non-limiting example embodiments for a “Spring Wave” grown out of a shield can with a hole(s). FIG. 9A depicts a top view, depicting the Spring Wave 920 and shield can vertical wall 922, and corresponding example welding points. In some embodiments, a distance between “wavelengths” of Spring Wave 920 can be in a range of 1 mm, and the Spring Wave 920 can be compressed between 0.2 to 0.4 mm. In some embodiments, the “welding points” may occur according to a predetermined frequency of wavelengths (e.g., every third or fourth point/apex, for example).

FIG. 9B depicts the heatsink (metallic ground) 902, thermally conductive material (e.g., foam/paste) 904, grounding springs 906 (e.g., Spring Wave, as in FIG. 9A), shield can 908, chip (e.g., active component) 910, PCB 912, noise 914 and ground 916.

According to some embodiments, the grounding springs 906 can operate and/or involve a similar constitution of the grounding springs, discussed supra. In some embodiments, the grounding springs 906 can be made out of one or multiple pieces of material (e.g., metallic and/or plastic, in a similar manner as the shield can discussed supra) that can be soldered (or welded) to the top of the shield can 908. In some embodiments, the grounding springs 906 and shield can 908 can be made out of one piece of material (e.g., cut or shaved, for example).

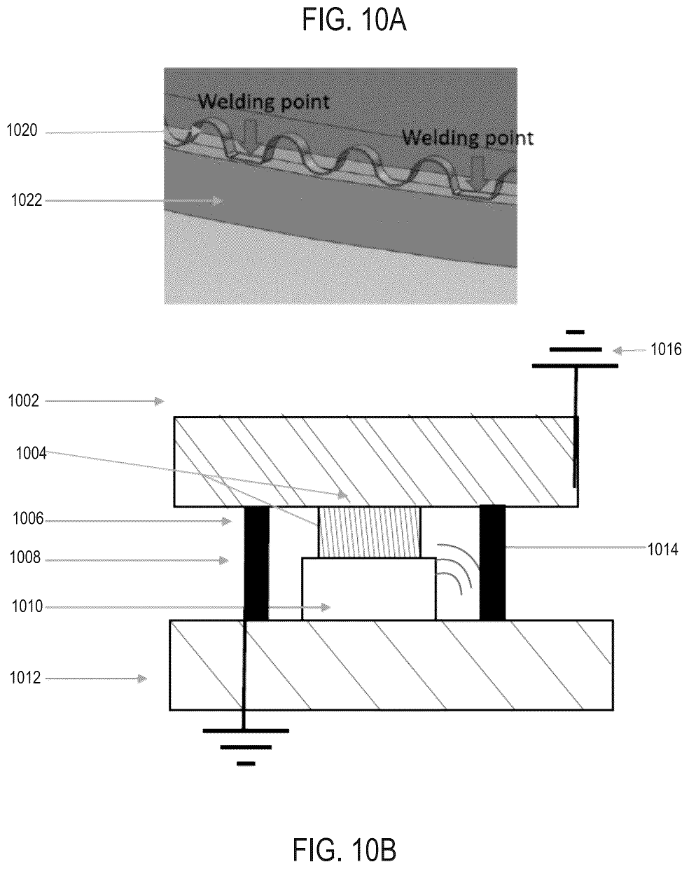

Turning to FIGS. 10A-10B, depicted are views from non-limiting example embodiments for a “Spring Wave” grown out of a heatsink. FIG. 10A depicts a top view, depicting the Spring Wave 1020 and shield can vertical wall 1022, and corresponding example welding points. In some embodiments, a distance between “wavelengths” of Spring Wave 1020 can be in a range of 1 mm, and the Spring Wave 1020 can be compressed between 0.2 to 0.4 mm. In some embodiments, the “welding points” may occur according to a predetermined frequency of wavelengths (e.g., every third or fourth point/apex, for example).

FIG. 10B depicts the heatsink (metallic ground) 1002, thermally conductive material (e.g., foam/paste) 1004, grounding springs 1006 (e.g., Spring Wave, as in FIG. 10A), shield can 1008, chip (e.g., active component) 1010, PCB 912, noise 1014 and ground 1016.

According to some embodiments, the grounding springs 906 can operate and/or involve a similar constitution of the grounding springs, discussed supra. In some embodiments, the grounding springs 1006 can be made out of one or multiple pieces of material (e.g., metallic and/or plastic, as discussed supra) that can be soldered (or welded) to the bottom of the heatsink 1002. As depicted, grounding springs 1006 can be configured to come into contact (e.g., touch) the top of the PCB 1012.

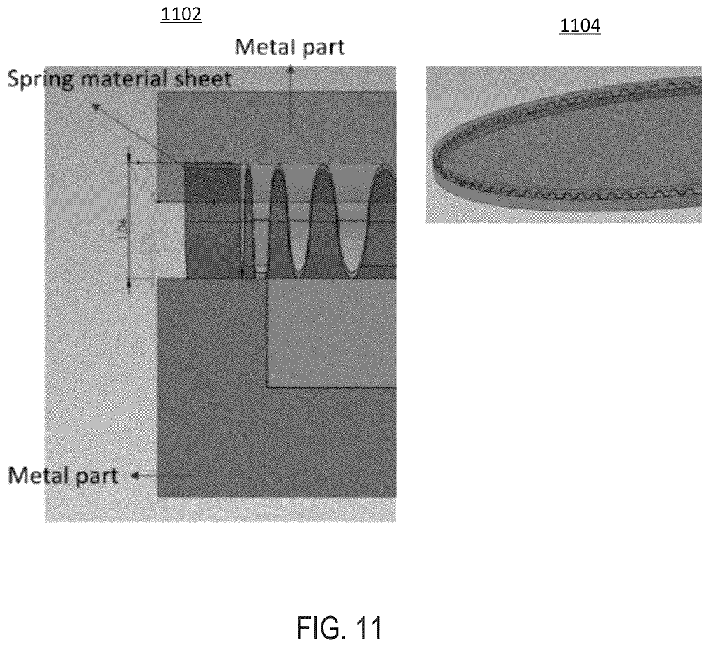

In FIG. 11, depicted are further non-limiting examples of Spring Wave grounding springs, which can be embodied in a similar manner as discussed above at least in relation to FIGS. 9A and 10A. According to some embodiments, in embodiment 1102, depicted is a spring material sheet and metal parts of the Spring Wave, which is further depicted in embodiment 1104. In some embodiments, such Spring Wave can have a compression height from 1.05 mm to 0.7 mm. Thus, as depicted in embodiment 1104, a created encapsulated volume can be created; however, while a circular embodiment is depicted, it should not be construed as limiting, as other shapes can be configured and implemented without departing from the scope of the instant application (e.g., line, rectangular, square, oval, and the like).

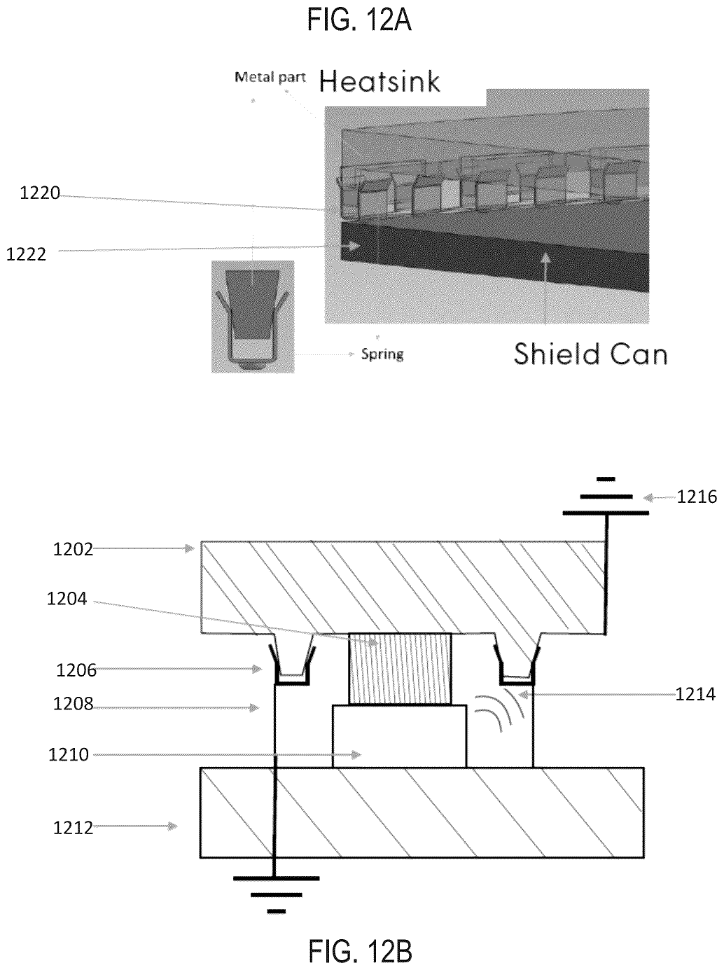

Turning to FIGS. 12A-12B, depicted are views from non-limiting example embodiments for a “U-Spring” grown out of a shield can with a hole(s). FIG. 12A depicts a top view, depicting a heatsink 1202, the U-Spring 1220 and shield can vertical wall 1222, and a shield can 1208. In some embodiments, a distance between each U-Spring 1220, as depicted in FIG. 12A can vary and/or can be according to a predetermined distance, which can depend on, but is not limited to, a type of device, type of active component, type of shield can material, amount of noise, amount of thermal conductivity, and the like, or some combination thereof.

FIG. 12B depicts the heatsink (metallic ground) 1202, thermally conductive material (e.g., foam/paste) 1204, grounding springs 1206 (e.g., U-Spring, as in FIG. 12A), shield can 1208, chip (e.g., active component) 1210, PCB 1212, noise 1214 and ground 1216.

According to some embodiments, the grounding springs 1206 can operate and/or involve a similar constitution of the grounding springs, discussed supra. In some embodiments, the grounding springs 1206 can be made out of one or multiple pieces of material (e.g., metallic and/or plastic, in a similar manner as the shield can discussed supra) that can be soldered (or welded) to the top of the shield can 1208. In some embodiments, the grounding springs 1206 and shield can 1208 can be made out of one piece of material (e.g., cut or shaved, for example).

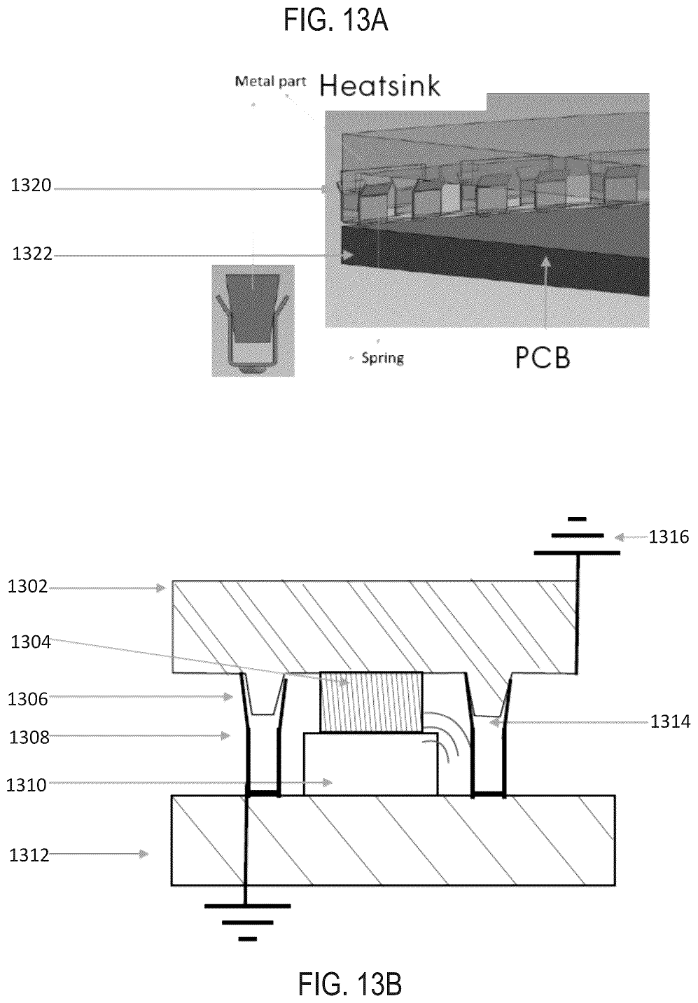

Turning to FIGS. 13A-13B, depicted are views from non-limiting example embodiments for a “U-Spring” soldered onto a PCB. FIGS. 13A-13B provide embodiments for use without a shield can.

FIG. 13A depicts a top view, depicting a heatsink 1302, the U-Spring 1320 and shield can vertical wall 1322, and PCB 1312. In some embodiments, a distance between each U-Spring 1320, as depicted in FIG. 13A can vary and/or can be according to a predetermined distance, which can depend on, but is not limited to, a type of device, type of active component, type of shield can material, amount of noise, amount of thermal conductivity, and the like, or some combination thereof.

FIG. 13B depicts the heatsink (metallic ground) 1302, thermally conductive material (e.g., foam/paste) 1304, grounding springs 1306 (e.g., U-Spring, as in FIG. 13A), U-Spring on PCB 1308, chip (e.g., active component) 1310, PCB 1312, noise 1314 and ground 1316.

According to some embodiments, the grounding springs 1306 can operate and/or involve a similar constitution of the grounding springs, discussed supra. In some embodiments, the grounding springs 1306/U-Spring 1308 can be made out of one or multiple pieces of material (e.g., metallic and/or plastic, in a similar manner as the shield can discussed supra) that can be soldered (or welded) to the top of the PCB 1312. In some embodiments, the grounding springs 1306 and U-Spring 1308 can be made out of one piece of material.

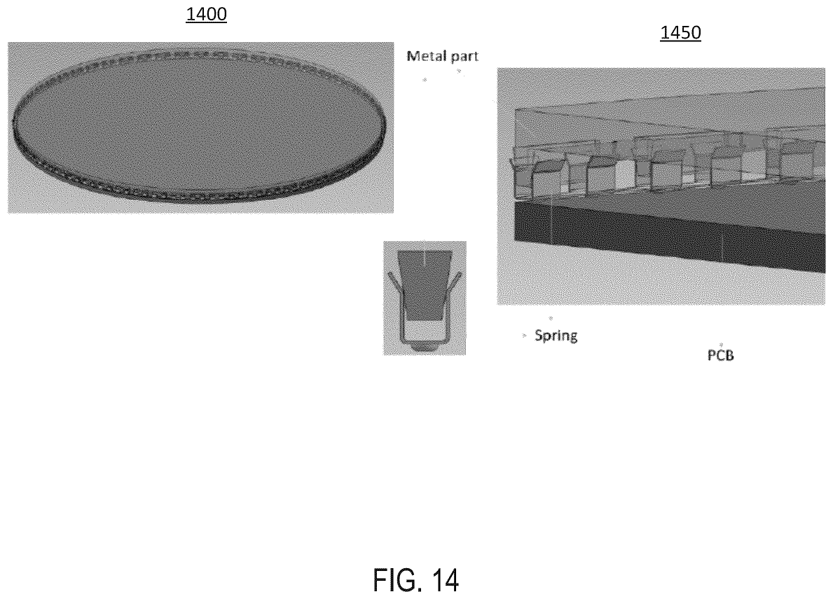

FIG. 14 depicts non-limiting example embodiments 1400 and 1450, which can correspond to implementations of the embodiments depicted in FIGS. 12A-13B. While a circular embodiment is depicted (1400), it should not be construed as limiting, as other shapes can be configured and implemented without departing from the scope of the instant application (e.g., line, rectangular, square, oval, and the like).

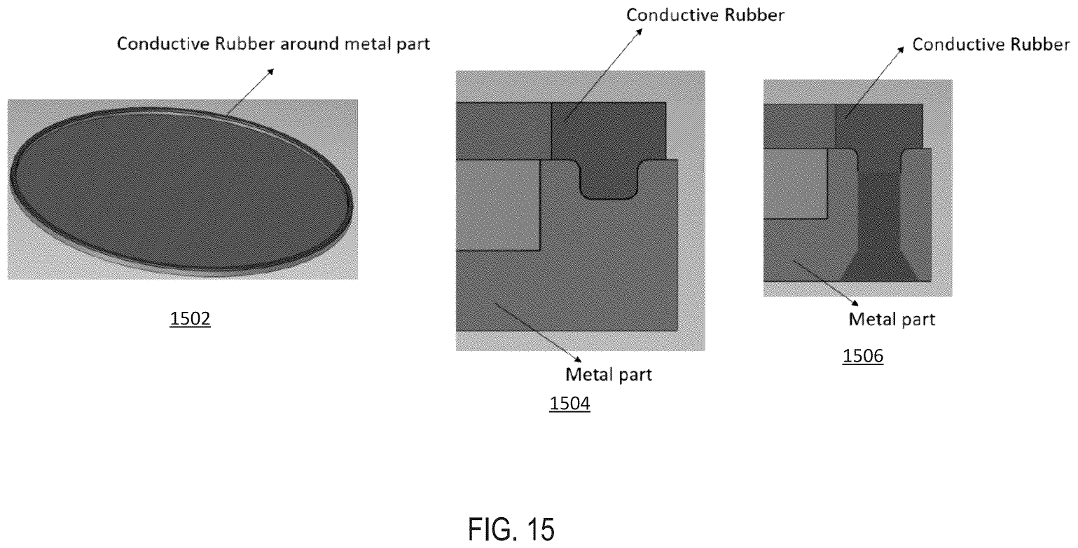

Turning to FIG. 15, depicted are non-limiting example embodiments 1502-1506, which depict non-limiting implementations of utilizing “over-molded conductive rubber” (instead of the grounding springs, discussed supra). As depicted in embodiments 1502-1504, the conductive rubber can be configured around the metal parts of a device's components according to different configurations, which can provide a reduction in noise and improvement in thermal conduction. In some embodiments, for example as in 1102, the rubber may encapsulate an entire PCB, or may correspond to encapsulation of specific components connected to a PCB.

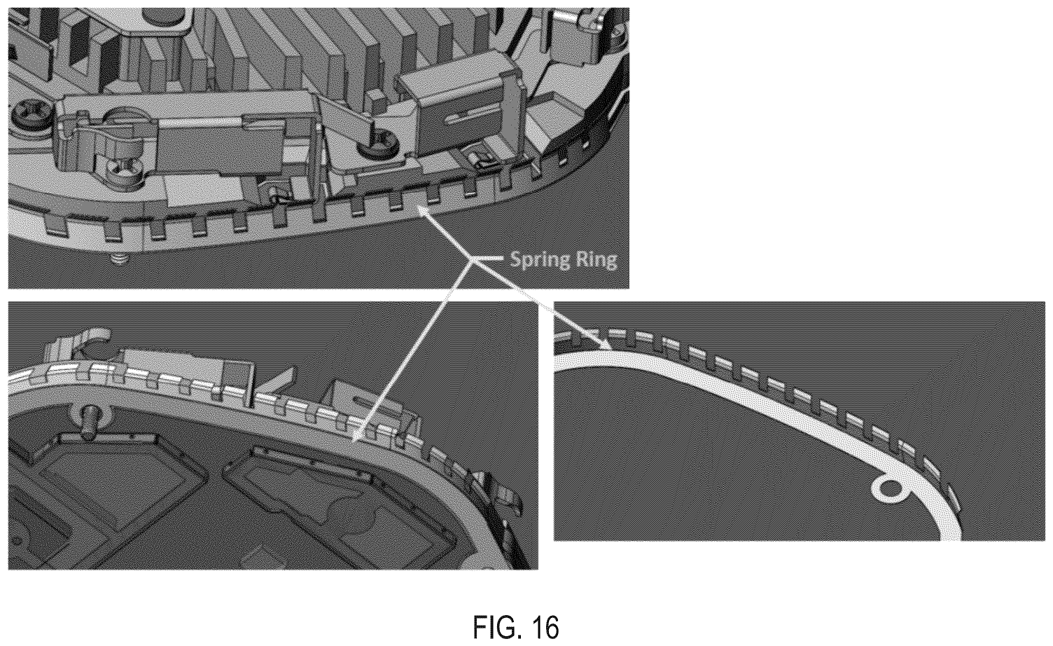

FIG. 16 depicts non-limiting example embodiments for a “clip ring”, where a spring ring can surround a PCB outline and a top heat spreader side wall. In some embodiments, the spring ring depicted in FIG. 16 may be mounted to the heatsink. In some embodiments, the configuration depicted in FIG. 16 can enhance the ground contact within components of a device, as well as connectivity between such components.

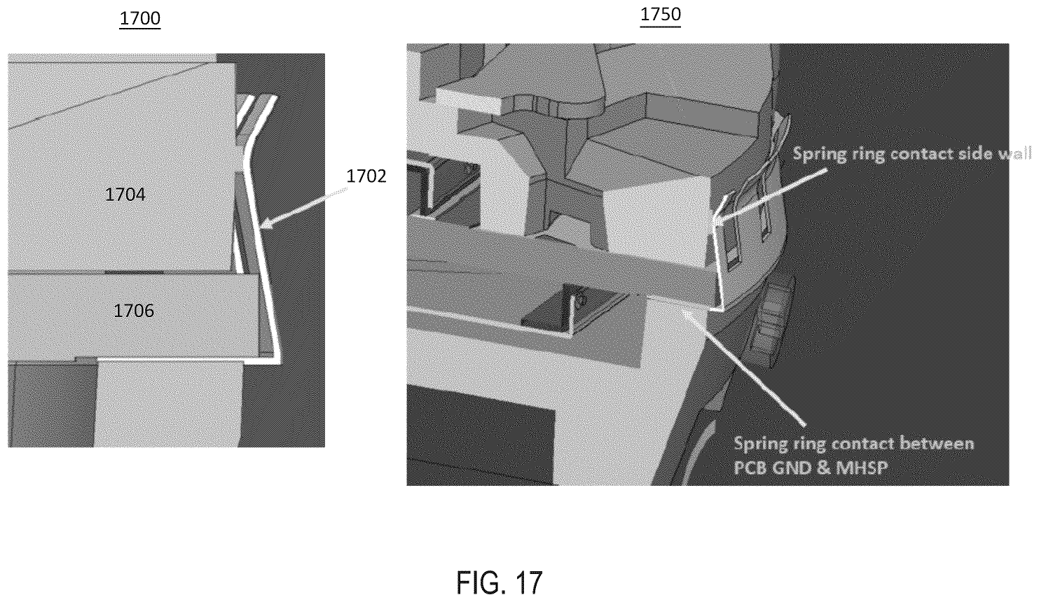

FIG. 17 depicts non-limiting example embodiments 1700 and 1750 for a clip ring, as discussed herein. In some embodiments, as in embodiment 1700, depicted are clip ring 1702, heatsink 1704 and PCB 1706. In some embodiments, ring 1702 can have a 2.5 mm spring arm that can provide elasticity around PCB 1706 and heatsink 1704. In some embodiments, as in embodiment 1750, the spring ring 1702 can contact a side wall, and may contact other components of a device, as discussed above.

The aforementioned examples are, of course, illustrative and not restrictive. At least some aspects of the present disclosure will now be addressed with reference to the following numbered clauses:

Clause 1. An apparatus including:
a circuit board, the circuit board having connected thereto an active component;
a heatsink positioned above the active component;
a thermally conductive material positioned between the active component and the heatsink;
a shield can positioned on the circuit board at least partially around the active component, wherein a top portion of the shield can is positioned between the active component and the heatsink; and
a set of grounding springs, the set of grounding springs positioned in relation to the top portion of the shield can, a proximate end of each grounding spring connecting to the shield can, a distal end of each grounding spring connecting to the heatsink.
   Clause 2. The apparatus of clause 1, wherein the shield can includes at least one hole on the top portion, wherein the at least one hole enables thermal conductivity within the apparatus.
   Clause 3. The apparatus of clause 1, wherein the connection between the shield can and the heatsink via the grounding springs enables a reduction of noise emanating from the active component.
   Clause 4. The apparatus of clause 1, wherein the set of grounding springs are connected to the shield can via soldering or welding.
   Clause 5. The apparatus of clause 1, wherein the set of grounding springs and shield can are formed from a same material.
   Clause 6. The apparatus of clause 1, wherein the set of grounding springs are a type selected from a group consisting of: wing-spring, M-spring, S-spring, C-spring, Tilt-spring, spring wave and U-spring.
   Clause 7. The apparatus of clause 1, wherein the set of grounding springs are associated with a spring clip, the spring clip encapsulating the circuit board.
   Clause 8. The apparatus of clause 1, wherein the apparatus includes a plurality of active components.
   Clause 9. The apparatus of clause 1, wherein the active component includes at least one of a radio, an antenna, an amplifier, module, switch, chip and/or memory.
   Clause 10. The apparatus of clause 9, wherein the radio can be at least one of a Wi-Fi radio, Bluetooth radio and cellular radio.
   Clause 11. The apparatus of clause 1, wherein the circuit board is a printed circuit board (PCB).
   Clause 12. The apparatus of clause, 1, wherein the apparatus is an electronic device.
   Clause 13. An apparatus including:
a circuit board, the circuit board having connected thereto an active component;
a heatsink positioned above the active component;
a thermally conductive material positioned between the active component and the heatsink;
a shield can positioned on the circuit board at least partially around the active component, the shield can including a grounding spring connected as a single piece, wherein a proximate end of the shield can connects to the circuit board, wherein a distal end of the shield can connects to the heatsink.
   Clause 14. The apparatus of clause 13, wherein the grounding spring includes a Spring Wave grounding spring.

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; x86 instruction set compatible processors, multi-core, or any other microprocessor or central processing unit (CPU). In various implementations, the one or more processors may be dual-core processor(s), dual-core mobile processor(s), and so forth.

Computer-related systems, computer systems, and systems, as used herein, include any combination of hardware and software. Examples of software may include software components, programs, applications, operating system software, middleware, firmware, software modules, routines, subroutines, functions, methods, procedures, software interfaces, application program interfaces (API), instruction sets, computer code, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

For the purposes of this disclosure a module is a software, hardware, or firmware (or combinations thereof) system, process or functionality, or component thereof, that performs or facilitates the processes, features, and/or functions described herein (with or without human interaction or augmentation). A module can include sub-modules. Software components of a module may be stored on a computer readable medium for execution by a processor. Modules may be integral to one or more servers, or be loaded and executed by one or more servers. One or more modules may be grouped into an engine or an application.

Functionality may also be, in whole or in part, distributed among multiple components, in manners now known or to become known. Thus, myriad software/hardware/firmware combinations are possible in achieving the functions, features, interfaces and preferences described herein. Moreover, the scope of the present disclosure covers conventionally known manners for carrying out the described features and functions and interfaces, as well as those variations and modifications that may be made to the hardware or software or firmware components described herein as would be understood by those skilled in the art now and hereafter.

While various embodiments have been described for purposes of this disclosure, such embodiments should not be deemed to limit the teaching of this disclosure to those embodiments. Various changes and modifications may be made to the elements and operations described above to obtain a result that remains within the scope of the systems and processes described in this disclosure.

What is claimed is:

1. An apparatus comprising:
a circuit board, the circuit board having connected thereto an active component;
a heatsink positioned above the active component;
a thermally conductive material positioned between the active component and the heatsink;
a shield can positioned on the circuit board at least partially around the active component, wherein a top portion of the shield can is positioned between the active component and the heatsink; and
a set of grounding springs, the set of grounding springs positioned in relation to the top portion of the shield can, a proximate end of each grounding spring connecting to the shield can, a distal end of each grounding spring connecting to the heatsink.

2. The apparatus of claim 1, wherein the shield can comprises at least one hole on the top portion, wherein the at least one hole enables thermal conductivity within the apparatus.

3. The apparatus of claim 1, wherein the connection between the shield can and the heatsink via the grounding springs enables a reduction of noise emanating from the active component.

4. The apparatus of claim 1, wherein the set of grounding springs are connected to the shield can via soldering or welding.

5. The apparatus of claim 1, wherein the set of grounding springs and shield can are formed from a same material.

6. The apparatus of claim 1, wherein the set of grounding springs are a type selected from a group consisting of: wing-spring, M-spring, S-spring, C-spring, Tilt-spring, spring wave and U-spring.

7. The apparatus of claim 1, wherein the set of grounding springs are associated with a spring clip, the spring clip encapsulating the circuit board.

8. The apparatus of claim 1, wherein the apparatus comprises a plurality of active components.

9. The apparatus of claim 1, wherein the active component comprises at least one of a radio, an antenna, an amplifier, module, switch, chip and/or memory.

10. The apparatus of claim 9, wherein the radio can be at least one of a Wi-Fi radio, Bluetooth radio and cellular radio.

11. The apparatus of claim 1, wherein the circuit board is a printed circuit board (PCB).

12. The apparatus of claim, 1, wherein the apparatus is an electronic device.

13. An apparatus comprising:
a circuit board, the circuit board having connected thereto an active component;
a heatsink positioned above the active component;
a thermally conductive material positioned between the active component and the heatsink;
a shield can positioned on the circuit board at least partially around the active component, the shield can comprising a grounding spring connected as a single piece, wherein a proximate end of the shield can connects to the circuit board, wherein a distal end of the shield can connects to the heatsink.

14. The apparatus of claim 13, wherein the grounding spring comprises a Spring Wave grounding spring.

15. An electronic device comprising:
a circuit board, the circuit board having connected thereto an active component;
a heatsink positioned above the active component;
a thermally conductive material positioned between the active component and the heatsink;
a shield can positioned on the circuit board at least partially around the active component, wherein a top portion of the shield can is positioned between the active component and the heatsink; and
a set of grounding springs, the set of grounding springs positioned in relation to the top portion of the shield can, a proximate end of each grounding spring connecting to the shield can, a distal end of each grounding spring connecting to the heatsink.

16. The electronic device of claim 15, wherein the shield can comprises at least one hole on the top portion, wherein the at least one hole enables thermal conductivity within the apparatus.

17. The electronic device of claim 15, wherein the connection between the shield can and the heatsink via the grounding springs enables a reduction of noise emanating from the active component.

18. The electronic device of claim 15, wherein the set of grounding springs and shield can are formed from a same material.

19. The electronic device of claim 15, wherein the set of grounding springs are a type selected from a group consisting of: wing-spring, M-spring, S-spring, C-spring, Tilt-spring, spring wave and U-spring.

20. The electronic device of claim 15, wherein the set of grounding springs are associated with a spring clip, the spring clip encapsulating the circuit board.
